(19) United States
(12) Patent Application Publication
(10) Pub. No.: US 2024/0347501 A1
(43) Pub. Date: Oct. 17, 2024

(54) METHODS AND APPARATUS FOR DIE-SHAPE MODIFICATION BONDING

(71) Applicants: Haris Khan Niazi, Brooklyn, NY (US); Yi Shi, Chandler, AZ (US); Bhaskar Jyoti Krishnatreya, Hillsboro, OR (US); Xavier F. Brun, Chandler, AZ (US)

(72) Inventors: Haris Khan Niazi, Brooklyn, NY (US); Yi Shi, Chandler, AZ (US); Bhaskar Jyoti Krishnatreya, Hillsboro, OR (US); Xavier F. Brun, Chandler, AZ (US)

(21) Appl. No.: 18/756,366

(22) Filed: Jun. 27, 2024

(51) Int. Cl. H01L 23/00; G05B 19/4099

(52) U.S. Cl. CPC H01L 24/80; G05B 19/4099; H01L 24/74; G05B 2219/45031; H01L 2224/74; H01L 2224/80047; H01L 2224/80123; H01L 2224/80908

(57) ABSTRACT

Methods and apparatus for die shape modification bonding are disclosed. A disclosed apparatus to adjust a die for bonding to a target includes interface circuitry, machine-readable instructions, and at least one processor circuit to be programmed by the machine-readable instructions to determine a shape profile of the die, determine an adjustment of the shape profile with respect to the bonding of the die to the target, and cause at least one of (i) an actuator or (ii) a vacuum device of a placer that carries the die to adjust the shape profile based on the determined adjustment.

### BACKGROUND

Hybrid bonding interconnect (HBI) is a relatively new type of solderless interconnect that enables a relatively tight interconnect pitch on the order of less than 9 micrometers (μm) and, therefore, significantly increases bandwidth density between die such that 100 million interconnects per square millimeter (mm²) is achievable with hybrid bonding (HB). The tighter die interconnect pitch can necessitate significantly higher placement accuracy during a bond operation. HBI can be implemented on a wafer-to-wafer (W2 W) or die-to-wafer (D2 W) level, and the bond can be accomplished by a room temperature dielectric bond subsequently followed by an anneal operation to form electrical joints.

During die-to-wafer or die-to-die (D2D) bonding, semiconductor chips are placed at specific locations on a target wafer (single wafer or reconstituted wafer, or a stacked wafer) or on a target die with a bond head nozzle assembly at room temperature. Upon placement, the dielectric surfaces on the two bonding interfaces bond together due to Van der Waals forces. Further, as a result of a post-bond anneal, the dielectrics form strong covalent bonds, and the metals form electrical joints between the two interfaces as a result of creep. The shape (bow/warpage) of a die/chiplet being bonded can play a significant role in a presence of voids between the two interfaces. In addition, as HB interconnect pitch is reduced to less than 1 μm to enable relatively higher interconnect densities, a die shape (bow/warpage) and inherent stresses can impact an interconnect pad overlap/overlay between the bonding interfaces and, thus, may lead to HB scaling errors at a die level.

### BRIEF DESCRIPTION OF THE DRAWINGS

FIG. 1 illustrates an example environment in which examples disclosed herein can be implemented.

FIG. 2 illustrates an example die adjustment system in accordance with teachings of this disclosure.

FIG. 3 illustrates an example process flow that can be implemented in examples disclosed herein.

FIGS. 4A-4I depict example placer implementations that can be implemented in examples disclosed herein.

FIG. 5 is a schematic overview of an example die shape control system that can implement examples disclosed herein.

FIG. 6 is a flowchart representative of example machine readable instructions and/or example operations that may be executed, instantiated, and/or performed by example programmable circuitry to implement the example die adjustment system of FIG. 2 and/or the example die shape control system of FIG. 5.

FIG. 7 is a block diagram of an example processing platform including programmable circuitry structured to execute, instantiate, and/or perform the example machine readable instructions and/or perform the example operations of FIG. 6 to implement the example die adjustment system of FIG. 2 and/or the example die shape control system of FIG. 5.

FIG. 8 is a block diagram of an example implementation of the programmable circuitry of FIG. 7.

FIG. 9 is a block diagram of another example implementation of the programmable circuitry of FIG. 7.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

### DETAILED DESCRIPTION

Methods and apparatus for die-shape bonding are disclosed. Hybrid bonding interconnect (HBI) is a relatively new type of solderless interconnect that enables a relatively tight interconnect pitch with hybrid bonding (HB). The tighter die interconnect pitch can necessitate significantly higher placement accuracy. In wafer-to-wafer (W2 W) bonding systems, top and bottom wafers are brought into close proximity and then a piston “push-pin” presses down at a center of the top wafer, thereby initiating contact and bond wave propagation. Due to this microscopic stretching of the top wafer with respect to the base wafer, a runout error that increases radially outward to a wafer edge can occur. The error can become more pronounced as an HB pitch decreases, which results in the pad size becoming smaller and increasing interconnect density.

To counter this runout effect, W2 W bonders have a mechanism called runout compensation, which can slightly stretch the base wafer, in the opposite direction as the top wafer, with mechanical processes utilizing multiple relatively small vacuum zones, which cancels the runout overlay error. In addition, a top chuck utilizes numerous small vacuum zones (e.g., zones that are concentrically arranged relative to one another) while a bottom chuck also includes numerous vacuum zones (e.g., vacuum zones arranged in radial slices).

In contrast to W2 W systems, die-to wafer (D2 W) bonders pick up die from a carrier (e.g., wafer, mylar, glass etc.) and align them to a target wafer for placement thereon. D2 W bonders can modulate bond force to a certain limited extent. Known D2 W bonders have a relatively little degree of control with respect to different types of die having different warpages/shape/stress profiles and will have an impact not only on overlay error when placing the die but also on die level bond wave propagation which could result in voids. In known systems, to compensate for differing die thicknesses/shapes/warpage/stresses, procuring bond head collaterals from vendors is necessitated, which can be costly and can also become obsolete once a new die design is introduced. Layer stack variation, multiple different chiplets per product, and chiplets sourced from different foundries (with different nodes, different metal and dielectric stacks, and different sizes, warpages, stresses, etc.) can introduce variance. Thus, a same bond head collateral may not be feasible for different chiplets, thereby resulting in significant cost and throughput implications caused by collateral changeover times, etc. Furthermore, with increased pitch reduction, runout can significantly impact overlay error at edges of a die during bonding, which can become critical for relatively larger die sizes.

Examples disclosed herein utilize an in-line die shape (bow/warpage) monitoring/measurement and feedback system that can mitigate and/or reduce the effects of warpage and/or runout of a die. Examples disclosed herein implement a unique bond head nozzle design that enables control of a shape of a die. Examples disclosed herein can adjust the shape of the die in an in-line processing during bonding, thereby enabling relatively void free bonding as well as relatively few scaling errors. Examples disclosed herein can account for a wide range of variation in die and, thus, can enable increased bonding reliability and reduce defects thereof. Examples disclosed can enable bond process correction to mitigate die shape variation and stresses related to bonding voids.

Examples disclosed herein utilize a sensor (e.g., an in-line sensor) to determine a shape profile of a die including out-of-plane warpage (e.g., based on an in-line die shape measurement made by the sensor, based on an output of the sensor as the die is moved to a target wafer and/or picked up from a carrier wafer, etc.). In turn, an adjustment of the shape profile and/or a shape/flexure of the die is determined. According to examples disclosed herein, an actuator and/or a vacuum device/generator carried by a placer (e.g., a bond head, a die bonder, a die placer, etc.) is implemented to displace and/or move at least a portion of the die. In some examples, the placer adjusts the shape of the die during bonding of the die to a target (e.g., a target wafer).

In some examples, the actuator includes at least one push pin. Additionally or alternatively, the placer includes and/or defines a vacuum device/generator having pneumatic channels that are utilized to generate a vacuum to pull on, adjust a shape of and/or carry the die. In some examples, an array or grid of push pins are utilized to adjust the shape of the die for bonding. In some such examples, the push pins include a channel or aperture for utilizing a vacuum to change a shape of the die. In some examples, at least one vacuum opening or aperture is utilized to adjust the shape of the die. For example, an array of vacuum openings can be utilized to adjust the shape of the die. In some examples, the actuators are organized as groups of push pins such that the pins can be actuated in groups to change the shape of the die and push the die to the target to initiate bonding. In some examples, the shape of the die is adjusted/corrected based on measurement, prior to bonding (e.g., the shape of the die is retrieved via a database prior to bonding). In some examples, the shape of the die is continuously adjusted/varied as the die is being bonded to the target such that measurements of the die are obtained during bonding.

In some examples, a shape model/profile of the die is utilized (e.g., retrieved from a database) to determine an adjustment of the die. Additionally or alternatively, a machine learning model is utilized to determine and/or control an adjustment of the die. In some such examples, the machine learning model may be trained based on shape profiles, die thickness, manufacturing identifiers (e.g., lot codes), layered construction, etc. in conjunction with results (e.g., reliability results, bonding results, etc.). In some examples, the sensor is carried by the aforementioned placer. The sensor can measure the three-dimensional shape profile of the die prior to the die being picked up or while the die is carried/supported by the placer, for example (in other words, the free-standing three-dimensional shape profile of the die can be measured by the sensor and/or the three-dimensional shape profile of the die while it is being supported by a carrier or a nozzle can also be measured).

As used herein, the term “actuator” refers to any device, system, mechanism and/or assembly that is utilized to move at least a portion of an object. Accordingly, the term “actuator” can refer to a device, system, mechanism and/or assembly that contacts at least a portion of an object or utilizes a force with respect to the object, etc. As used herein, the terms “vacuum device,” “vacuum generator,” and “vacuum array” refer to a device, component, assembly and/or system that utilizes a fluid to generate a vacuum for movement and/or carrying of an object.

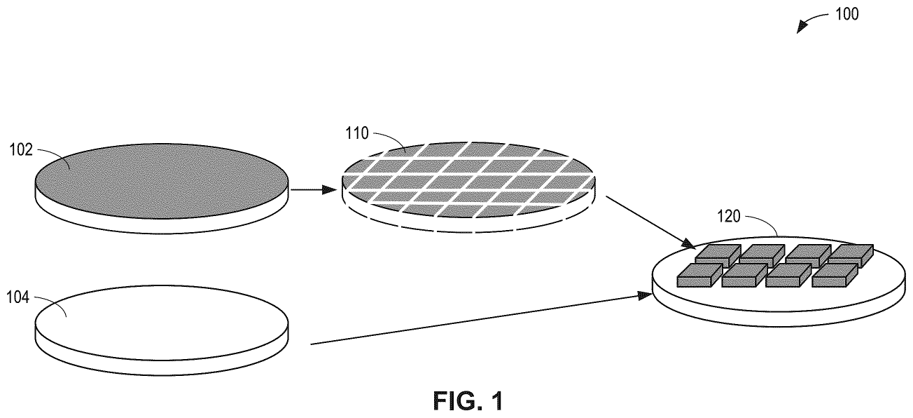

FIG. 1 illustrates an example environment 100 in which examples disclosed herein can be implemented. As can be seen in the view of FIG. 1, a first wafer (e.g., a wafer constituting groups of die to be bonded) 102 and a target (e.g., a target wafer) 104, which is herein referred to as a “second wafer,” are shown. In FIG. 1, a dicing process (e.g., a plasma discing process) 110 is utilized to subdivide the first wafer 102 into individual die such that the singulated chips can be supported on a carrier wafer or on a film frame based carrier. In turn, in a bonding process 120, the aforementioned die are bonded to the second wafer 104 in a D2 W process. Examples disclosed herein can be effective in accounting for shape/runout/warpage variations of the die for a D2 W bonding process (e.g. fusion bonding, hybrid bonding, thermal compression bonding, etc.), for example.

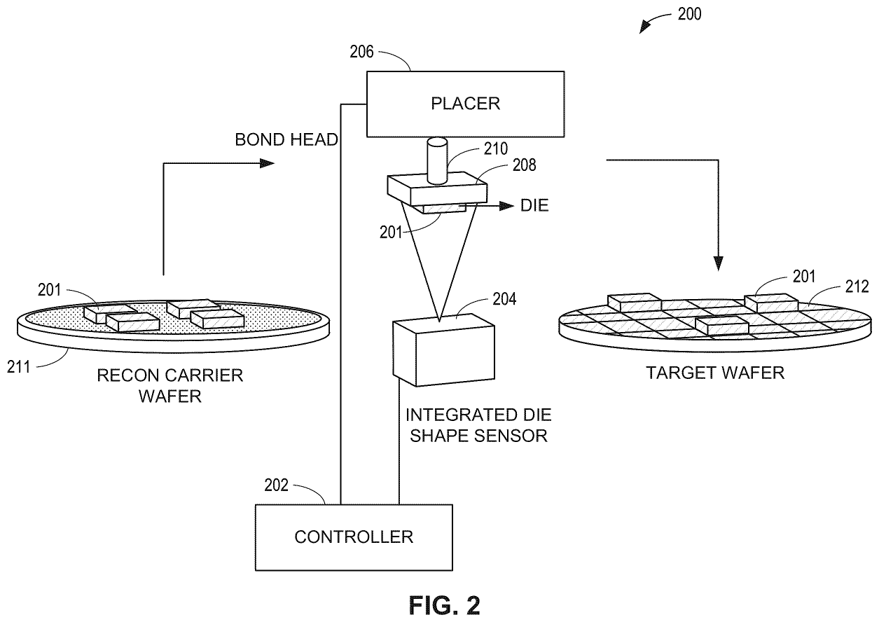

FIG. 2 illustrates an example die adjustment system 200 in accordance with teachings of this disclosure. The die adjustment system 200 of the illustrated example is implemented to bond and/or couple die 201 to a target. The example die adjustment system 200 includes a controller (e.g., a die bonder controller, a bond head controller, etc.) 202, a sensor (e.g., a die shape sensor, a 3D profiler, a surface measurement sensor, an integrated shape sensor, a laser triangulation sensor, a laser-based holography sensor, an interferometry system, a Shadow Moiré sensor, etc.) 204, and a placer (e.g., a die placer, a bond head, etc.) 206. In turn, the example placer 206 includes and/or is operatively coupled to a bond head 208 carried by a support 210.

In this example, the die 201 are removed from a carrier wafer/film frame carrier (FFC) 211 and bonded to a target 212, which is a target wafer in this example (and herein referred to as such). According to examples disclosed herein, the sensor 204 is to measure a shape profile of the die 201 as the die 201 are carried by the placer 206 toward the target wafer 212. In turn, the bond head 208 adjusts an overall shape of the die 201. As a result, the die 201 can be bonded to the target wafer 212 while reducing a probability/occurrence of defective bonds, voids or other manufacturing defects.

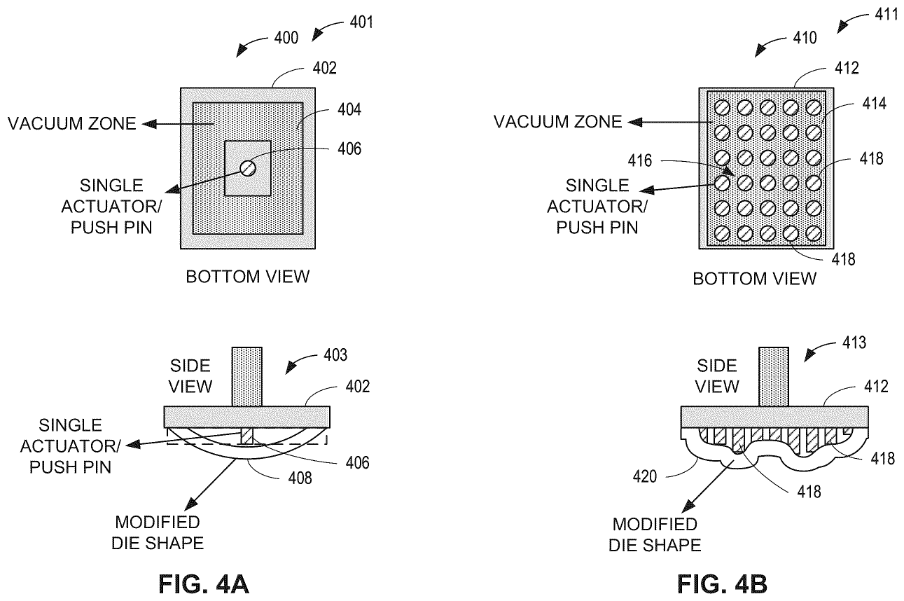

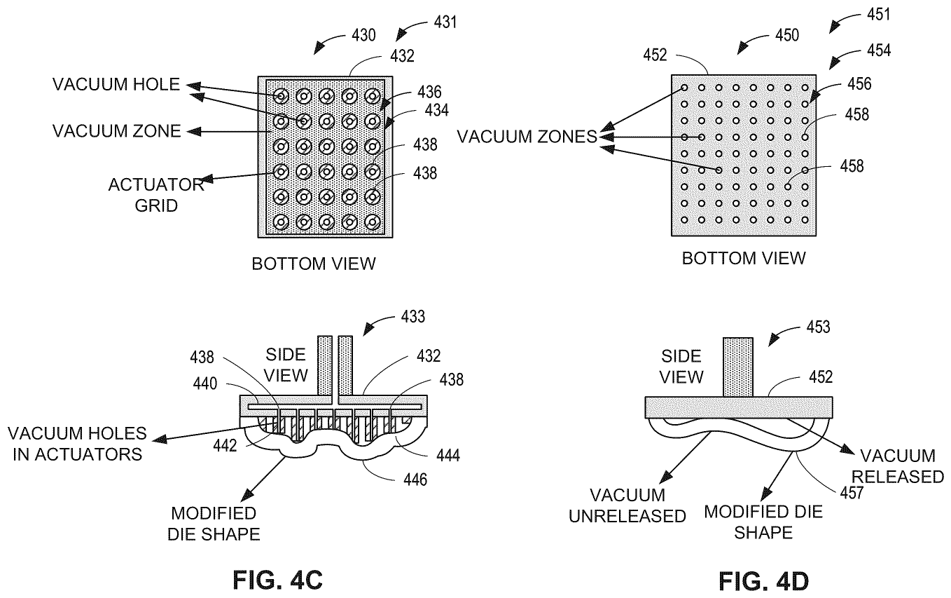

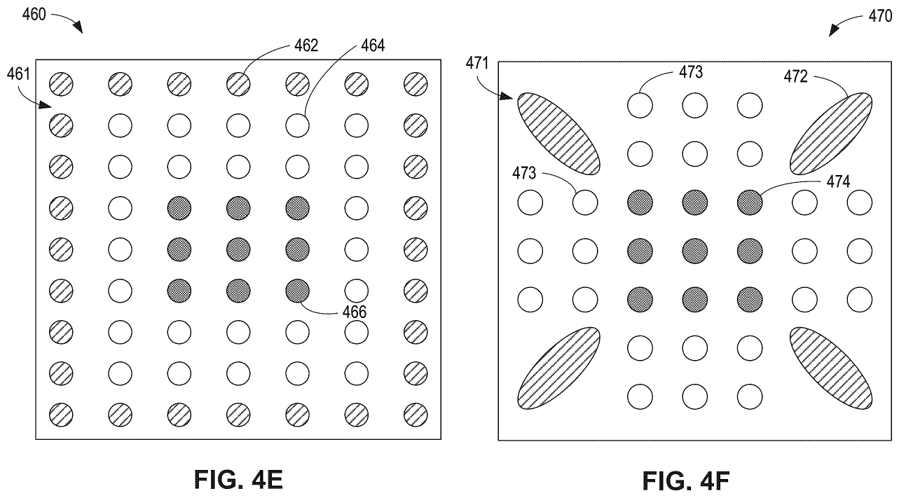

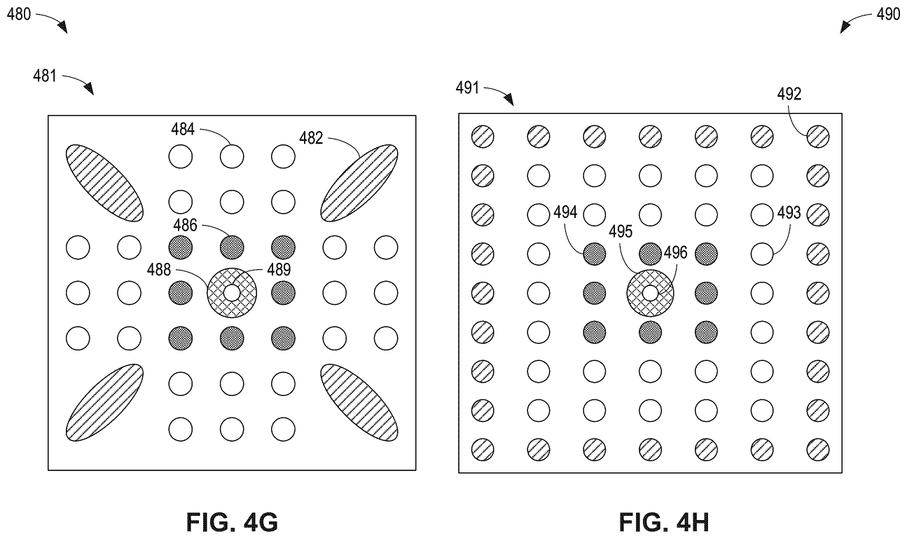

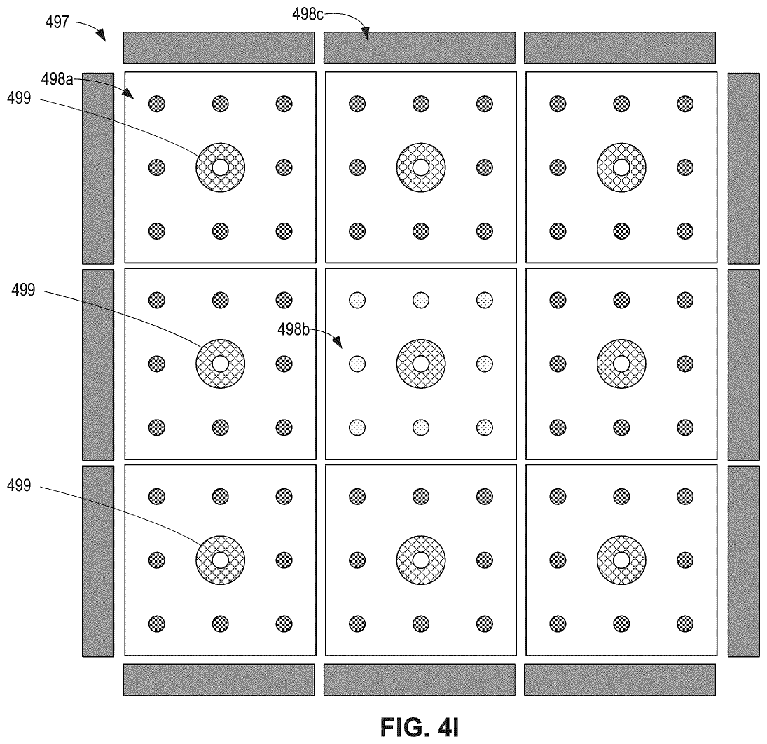

According to examples disclosed herein, to adjust the shape profile of the individual die 201, the placer 206 includes, carries and/or supports an actuator, a group of actuators and/or a vacuum device that shifts and/or displaces at least a portion of ones of the die 201, thereby adjusting a shape profile (e.g., a flexure, a flexure profile, a warp characteristic, a warpage, etc.) thereof. As will be shown in examples disclosed below in connection with FIGS. 4A-4I, the shape profile of the die 201 can be adjusted with an array of pushing elements and/or vacuum elements/openings/apertures, for example. However, any other appropriate type of actuation device, displacement device, mechanical adjustment device, pneumatic device and/or movement mechanism can be implemented instead.

While examples disclosed herein are shown in the context of a D2 W process, examples disclosed herein can be applied to any other appropriate application of die bonding/assembly. Accordingly, examples disclosed herein can be applied to coupling/bonding die to targets other than a target wafer, for example.

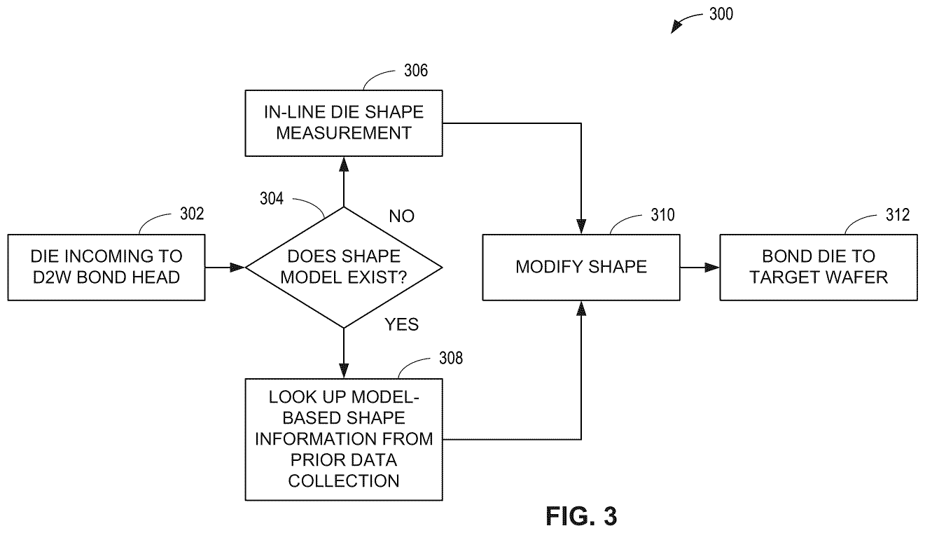

FIG. 3 illustrates an example process flow 300 that can be implemented in examples disclosed herein. In the illustrated example of FIG. 3, a die (e.g., the die 201 shown in FIG. 2) is to be carried and/or supported by a bond head is identified. For example, a unique identifier of the die is utilized and/or scanned to retrieve shape information and/or data of the die. At block 302, a die (e.g., an incoming die) is brought to the bond head.

In some examples, at block 304, it is determined whether a shape model (e.g., a shape/flexure profile of the die, a flexure profile, a 3D profile, etc.) exists and/or is accessible (e.g., in a database, pre-measured readings, lot measurements, etc.). If the shape model exists and/or is accessible (control of the process proceeds to block 308). Otherwise, the process proceeds to block 306.

At block 306, an in-line die shape measurement is obtained and/or measured by a sensor (e.g., the sensor 204 of FIG. 2). In this example, the sensor is utilized to measure multiple points and/or areas of the die to generate and/or determine the in-line die shape measurement. According to examples disclosed herein, a shape and/or flexure profile of the die is measured (e.g., while or prior to the die being picked up for bonding to a target wafer).

At block 308, in some examples, data and/or information corresponding to a shape (e.g., a shape profile) of the die is obtained from the model-based shape information. For example, a serial number, symbol and/or identifier of the die is utilized to obtain the data and/or the information corresponding to the shape.

At block 310, the shape of the die is adjusted and/or modified. According to some examples, the shape of the die is adjusted based on displacing and/or moving at least a portion of the die with an actuator and/or a vacuum device including an array of vacuum apertures to vary a flexure, warpage and/or flatness thereof, for example. The vacuum apertures can have different shapes. Some examples of aperture shapes are circular, linear, or elliptical apertures). According to some examples disclosed herein, the shape of the die is adjusted until and/or while the die is being bonded to the target wafer.

In some examples, based on existing shape data model (or recently collected shape data), the aforementioned bond head modulates a shape of the die to reduce voids (e.g., between the die and the target) with a relatively low degree of overlay error bonding. For example, the bond head can assign weights/weighting to individual push-pin actuators or individual vacuum ports/openings based on pixel-wise topography data collected from an integrated shape sensor to reduce effects of local peaks/troughs and ensure relatively uniform bond wave propagation.

At block 312, the die is bonded to the aforementioned target wafer. In some examples, the shape of ones of the die is adjusted by the actuator and/or the vacuum ports/openings as the die is bonded to the target wafer (e.g., during a bonding process). In some such examples, an adjustment and/or adjustment profile of the die varies as the die is bonded to the target wafer (e.g., varies with respect to time during a bonding process). In other words, the displacement of portions of the individual die can be varied at different times or stages of the bonding process.

FIGS. 4A-4I depict example placers (e.g., bond head, picker, pick and place, etc.) 400, 410, 430, 450, 460, 470, 480, 490, 497, respectively, that can be implemented in examples disclosed herein. Turning to FIG. 4A, the example placer 400 is shown. In the view of FIG. 4A, a bottom view 401 is shown above a side view 403. In this example, the placer 400 includes a body 402 including a vacuum zone 404 (defined by a vacuum device/generator) and an actuator 406, which is implemented as a movable pin (e.g., a push pin) in this example and further referred to herein as the pin 406. According to examples disclosed herein, the vacuum zones 404 can be independently controlled as different groups based on a design (e.g., groups of the vacuum zones 404 can be divided into grids, groups of the vacuum zones 404 can be divided/designated as a function of distance from center of a die to an edge of the die) and the vacuum(s) can be turned on and off in a deterministic manner based on die shape profiles.

As can be seen in the side view 403, the example pin 406 can be moved and/or displaced upward and downward (in the side view 403 of FIG. 4A) such that a shape of a die 408 can be adjusted via movement (e.g., linear movement) of the pin 406. For example, at least a portion of the die 408 can be pushed and/or displaced with the pin 406, thereby adjusting a bow, a shape profile and/or a flexure thereof. Accordingly, the shape of the die 408 can be adapted for bonding to a target, for example. In this example, the vacuum zone 404 is defined as an area surrounding the pin 406. The vacuum zone 404 can have multiple groups of independently controlled vacuum zones, as mentioned above. While a single pin is shown in this example, in some examples, multiple pins and/or actuators can be implemented instead. In some such examples, the pins and/or actuator can be arranged in a grid or dispersed between vacuum apertures. The vacuum apertures can have different shapes such as, but not limited to, circular shapes, linear shapes, elliptical shapes, etc. Further, apertures and/or actuators can be implemented on the nozzle or bond head designed to control the shape on the edges and corners of the die.

FIG. 4B depicts a bottom view 411 and a side view 413 of the example placer 410. In this example, the placer 410 includes a body 412 which, in contrast to the example of FIG. 4A, carries and/or supports a vacuum zone (e.g., a vacuum zone surface) or vacuum device/generator 414 having an array 416 of movable pins 418. In the illustrated example of FIG. 4B, each of the movable pins 418 can be independently controlled and moved to adjust a shape of a die 420, as can be seen in the side view 413 shown in the bottom of FIG. 4B. In this example, a vacuum zone surrounds and/or encompasses the movable pins 418.

Turning to FIG. 4C, a bottom view 431 and a side view 433 of the aforementioned example placer 430 is shown. In this example, the placer 430 includes a body 432 that carries and/or supports a vacuum zone 434 having an array 436 of apertures (e.g., channels, fluid apertures, vacuum apertures, etc.) 438. In the illustrated example of FIG. 4C, channels 440 direct flow to apertures (e.g., channels) of actuators (e.g., actuator pins) 442 with each of the actuators 442 being independently movably controlled (in conjunction with a vacuum or pull action from the channels 440) to affect a shape, flexure and/or bow of a die 444, as can be seen in the side view 433 shown in the bottom of FIG. 4C. The example actuators 442 can each have a respective aperture extending longitudinally therethrough and fluidly coupled to the channels 440. According to examples disclosed herein, independent distance control and/or force control can be utilized to enable deterministic die shape adjustment, bond wave propagation and/or bond void reduction/elimination. Accordingly, an adjusted shape profile 446 of the die 444 can have a significant quantity and/or number of contours and/or an irregular profile, which can be advantageous in bonding to a target. In this example, a vacuum zone surrounds and/or encompasses the apertures 438. Additionally or alternatively, in some examples, different apertures are utilized at different times (e.g., a sequence or order of utilizing different vacuums and/or vacuum groups is utilized) to adjust a shape of the die 444.

FIG. 4D depicts a bottom view 451 and a side view 453 of the aforementioned example placer 450. In this example, the placer 450 includes a body 452 that carries and/or supports a vacuum device 454. The example vacuum device 454 includes an array 456 of vacuums (e.g., vacuum apertures, vacuum elements, vacuum openings, vacuum channels, etc.) 458. As can be seen in the side view 453 shown in the bottom of FIG. 4D, the shape of a die 457 can be adjusted at multiple different points/areas by controlling ones of the vacuums 458 of the body 452 independently of one another, thereby enabling a relatively high degree of control of the shape of the die 457. In this example, a vacuum zone is defined by the vacuums 458 based on the vacuums being independently controllable, for example. As a result, examples disclosed herein may affect a die shape adjustment in conjunction with bond wave propagation control and bond void mitigation without necessitating an actuator, for example.

FIG. 4E is a bottom view of the example placer 460. The example placer 460 includes a vacuum device 461 which, in turn, includes independently controlled vacuum aperture groups 462, 464, 466. In operation, the vacuum groups 462, 464, 466 can be independently operated to adjust a shape of a die. In other words, different groups of apertures can be operated to change a shape of the die. In this particular example, a pin and/or an actuator is not implemented.

FIG. 4F is a bottom view of the example placer 470. The example placer 470 includes a vacuum device 471 having independently controlled vacuum aperture groups 472, 473, 474. In operation, the vacuum groups 472, 473, 474, can be independently operated to adjust a shape of a die. According to some examples, apertures of the group 472 can be elongated, ellipsoid, slot-shaped and/or irregularly shaped. Further apertures of the groups 472, 473, 474 can have different shapes and/or sizes from one another.

FIG. 4G is a bottom view of the example placer 480. The example placer 480 includes a vacuum device 481 having independently controlled vacuum aperture groups 482, 484, 486. The example placer 480 is similar to the example placer 470 of FIG. 4F, but instead includes a single actuator 488 in combination with a vacuum and/or vacuum grid implementation. In some examples, the actuator 488 includes a vacuum channel or aperture 489 (in addition to the aforementioned vacuum device 481. While the single actuator 488 is shown, multiple actuators can be implemented instead. For example, multiple actuators can be dispersed between vacuum apertures. In some examples, multiple actuators and multiple vacuum zones are utilized on the same placer.

FIG. 4H is a bottom view of the example placer 490. The example placer 490 includes a vacuum device 491 having independently controlled vacuum aperture groups 492, 493, 494. The example placer 490 is similar to the example placer 460 of FIG. 4E, but instead includes a single actuator 495, which may be positioned at a geometric center and/or centroid of a plane/surface of the placer 490, for example. According to some examples disclosed herein, the actuator 495 includes a vacuum channel or aperture 496. In some examples, multiple actuators and multiple vacuum zones are utilized on the same placer.

FIG. 4I depicts an example placer 497 having multiple vacuum zones 498 (hereinafter vacuum zones 498a, 498b, 498c, etc.) and multiple actuators 499. In other words, an array of the vacuum zones 498 and the actuators 499 is defined. In some examples, apertures of the individual vacuum zones can be individually controlled (e.g., apertures across the placer 497 can be individually controlled). Additionally or alternatively, the vacuum zones 498 and/or the apertures of the vacuum zones 498 can be grouped to deactivate when at least one of the actuators 499 is turned on/operated. In some examples, multiple types of vacuum devices (e.g., a grid of apertures with at least one vacuum device at a periphery of the placer 497). According to some examples disclosed herein, vacuum devices and/or apertures can have different force and/or suction levels (e.g., based on aperture shape, suction levels, group suction levels, etc.).

An aspect or feature described in any of the examples disclosed herein can be combined or utilized with another example, as appropriate. In other words, any aspect described herein can be implemented in another example.

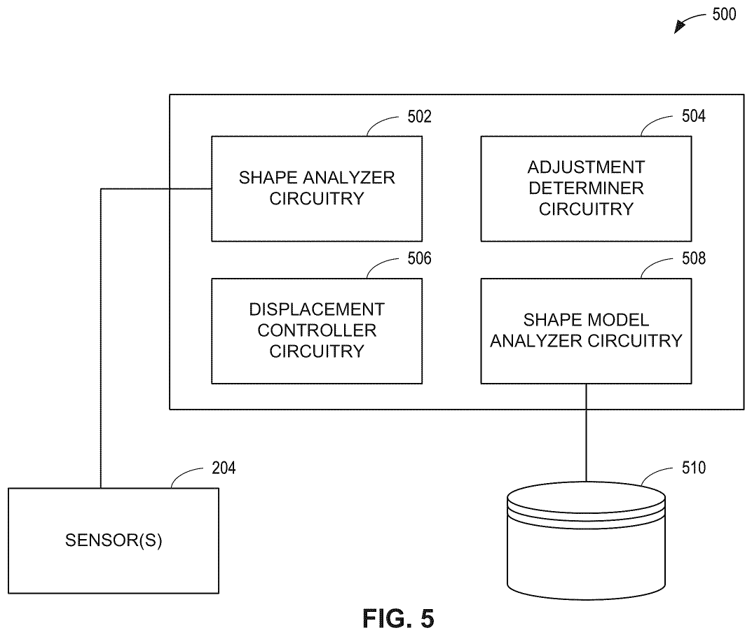

FIG. 5 is a block diagram of an example implementation of an example die shape control system 500 to control bonding of die to a substrate and/or wafer. The example die shape control system 500 can be implemented in the controller 202, the sensor 204 and/or the placer 206 shown in FIG. 2. The die shape control system 500 of FIG. 5 may be instantiated (e.g., creating an instance of, bring into being for any length of time, materialize, implement, etc.) by programmable circuitry such as a Central Processor Unit (CPU) executing first instructions. Additionally or alternatively, the die shape control system 500 of FIG. 5 may be instantiated (e.g., creating an instance of, bring into being for any length of time, materialize, implement, etc.) by (i) an Application Specific Integrated Circuit (ASIC) and/or (ii) a Field Programmable Gate Array (FPGA) structured and/or configured in response to execution of second instructions to perform operations corresponding to the first instructions. It should be understood that some or all of the circuitry of FIG. 5 may, thus, be instantiated at the same or different times. Some or all of the circuitry of FIG. 5 may be instantiated, for example, in one or more threads executing concurrently on hardware and/or in series on hardware. Moreover, in some examples, some or all of the circuitry of FIG. 5 may be implemented by microprocessor circuitry executing instructions and/or FPGA circuitry performing operations to implement one or more virtual machines and/or containers.

The example die shape control system 500 includes example shape analyzer circuitry 502, example adjustment determiner circuitry 504, example displacement controller circuitry 506, example shape model analyzer circuitry 508 and an example data storage 510. According to examples disclosed herein, the die shape control system 500 includes and/or is coupled to the example sensor(s) 204.

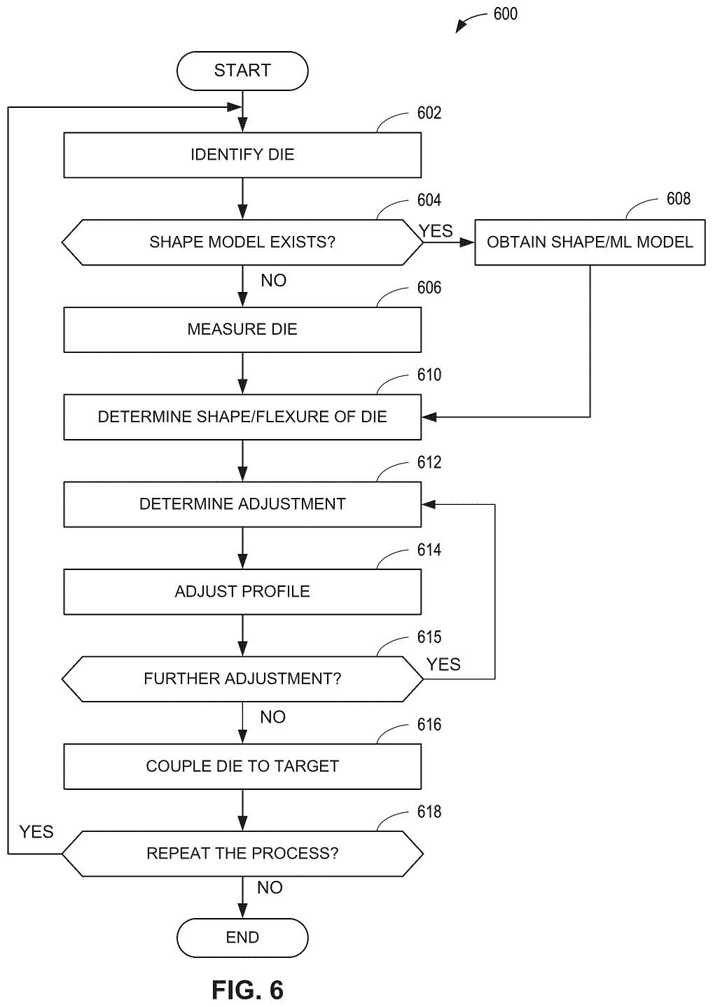

According to examples disclosed herein, the shape analyzer 502 is implemented to determine and/or characterize a shape, a shape profile, a flexure distribution, a warpage, a flexure, etc. of a die based on sensor output from a sensor (e.g., the sensor 204 of FIG. 2). For example, the shape analyzer 502 utilizes the output of the sensor to determine a 3D profile of the die. According to some examples disclosed herein, the sensor output corresponds to a flexure and/or warpages of the die prior to being picked up by a placer, such as the example placer 206 shown in FIG. 2. In some such examples, the sensor is part of and/or integrated with the placer. In some examples, the shape analyzer 502 is instantiated by programmable circuitry executing shape analyzer instructions and/or configured to perform operations such as those represented by the flowchart of FIG. 6.

In this example, the adjustment determiner circuitry 504 is implemented to determine and/or calculate an adjustment of the die (e.g., adjustment of a shape of the die). In some examples, the adjustment determiner circuitry 504 determines an adjustment profile to adjust a shape of the die as the die is placed onto and/or coupled to a wafer (e.g., the target wafer 212). In some examples, the shape of the die is adjusted as the die is bonded to the aforementioned wafer. In some examples, the adjustment determiner circuitry 504 is instantiated by programmable circuitry executing adjustment determiner instructions and/or configured to perform operations such as those represented by the flowchart of FIG. 6.

According to examples disclosed herein, the displacement controller circuitry 506 is implemented to control an actuator or other shape adjustment device (e.g., a movable pin array, a vacuum array, a vacuum device, a vacuum generator, etc.) to adjust a shape/profile of the die based on the determined and/or calculated adjustment. In some examples, the displacement controller circuitry 506 is instantiated by programmable circuitry executing displacement controller instructions and/or configured to perform operations such as those represented by the flowchart of FIG. 6.

In some examples, a shape model analyzer circuitry 508 is implemented to develop, generate and/or train a model for determining a model corresponding to die shape adjustments. In a particular example, the model is a machine-learning (ML) model that is trained with die measurements, shape adjustments die thickness, etc. in conjunction with corresponding results (e.g., bonding results, Confocal Scanning Acoustic Microscopy (CSAM) results, yield results, reliability results, assembled profile results, life expectation results, etc.). In some such examples, the trained model is utilized to determine an adjustment of a die given at least one measurement thereof (e.g., a measured 3D profile, a spatial profile, a flexure profile, etc.). Additionally or alternatively, the shape model analyzer circuitry 508 determines an extent to which the die shape is to be adjusted (e.g., based on further processing and/or adjustments of the die). According to some examples disclosed herein, the shape model analyzer circuitry 508 trains the model based on die flexure with respect to bonding adhesion or any other appropriate measurable parameter. In some examples, the shape model analyzer circuitry 508 is instantiated by programmable circuitry executing shape model analyzer instructions and/or configured to perform operations such as those represented by the flowchart of FIG. 6.

In some examples, the data storage 510 is implemented to store shape profile data, individual die data, flexure corrections, shape adjustment information, etc. In some examples, the data storage 510 is implemented to store trained machine learning models and/or data utilized to train the machine learning models.

While an example manner of implementing the die shape control system 500 of FIG. 5 is illustrated in FIG. 5, one or more of the elements, processes, and/or devices illustrated in FIG. 5 may be combined, divided, re-arranged, omitted, eliminated, and/or implemented in any other way. Further, the example shape analyzer 502, the example adjustment determiner circuitry 504, the example displacement controller circuitry 506, the example shape model analyzer circuitry 508, and/or, more generally, the example die shape control system 500 of FIG. 5, may be implemented by hardware alone or by hardware in combination with software and/or firmware. Thus, for example, any of the example shape analyzer 502, the example adjustment determiner circuitry 504, the example displacement controller circuitry 506, the example shape model analyzer circuitry 508, and/or, more generally, the example die shape control system 500, could be implemented by programmable circuitry in combination with machine readable instructions (e.g., firmware or software), processor circuitry, analog circuit(s), digital circuit(s), logic circuit(s), programmable processor(s), programmable microcontroller(s), graphics processing unit(s) (GPU(s)), digital signal processor(s) (DSP(s)), ASIC(s), programmable logic device(s) (PLD(s)), and/or field programmable logic device(s) (FPLD(s)) such as FPGAs. Further still, the example die shape control system 500 of FIG. 5 may include one or more elements, processes, and/or devices in addition to, or instead of, those illustrated in FIG. 5, and/or may include more than one of any or all of the illustrated elements, processes and devices.

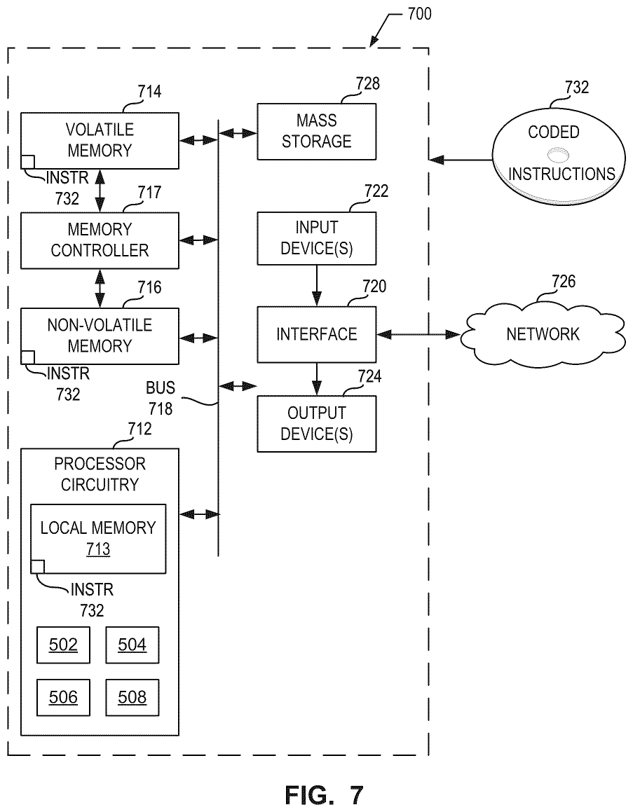

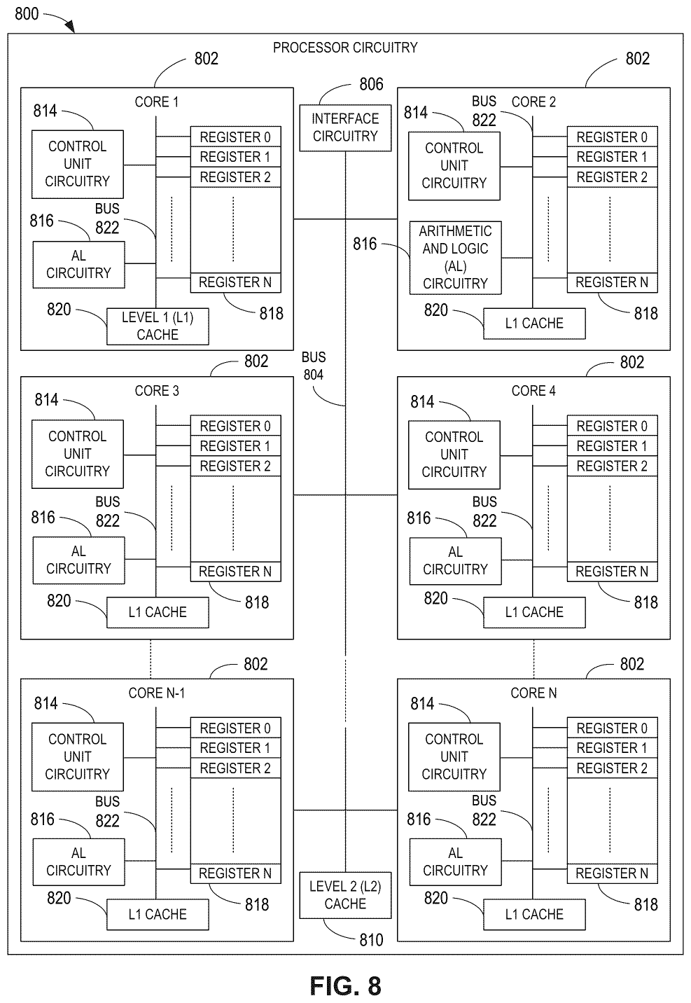

A flowchart representative of example machine readable instructions, which may be executed by programmable circuitry to implement and/or instantiate the die shape control system 500 of FIG. 5 and/or representative of example operations which may be performed by programmable circuitry to implement and/or instantiate the die shape control system 500 of FIG. 5, is shown in FIG. 6. The machine readable instructions may be one or more executable programs or portion(s) of one or more executable programs for execution by programmable circuitry such as the programmable circuitry 712 shown in the example processor platform 700 discussed below in connection with FIG. 7 and/or may be one or more function(s) or portion(s) of functions to be performed by the example programmable circuitry (e.g., an FPGA) discussed below in connection with FIGS. 8 and/or 9. In some examples, the machine readable instructions cause an operation, a task, etc., to be carried out and/or performed in an automated manner in the real world. As used herein, “automated” means without human involvement.

The program may be embodied in instructions (e.g., software and/or firmware) stored on one or more non-transitory computer readable and/or machine readable storage medium such as cache memory, a magnetic-storage device or disk (e.g., a floppy disk, a Hard Disk Drive (HDD), etc.), an optical-storage device or disk (e.g., a Blu-ray disk, a Compact Disk (CD), a Digital Versatile Disk (DVD), etc.), a Redundant Array of Independent Disks (RAID), a register, ROM, a solid-state drive (SSD), SSD memory, non-volatile memory (e.g., electrically erasable programmable read-only memory (EEPROM), flash memory, etc.), volatile memory (e.g., Random Access Memory (RAM) of any type, etc.), and/or any other storage device or storage disk. The instructions of the non-transitory computer readable and/or machine readable medium may program and/or be executed by programmable circuitry located in one or more hardware devices, but the entire program and/or parts thereof could alternatively be executed and/or instantiated by one or more hardware devices other than the programmable circuitry and/or embodied in dedicated hardware. The machine readable instructions may be distributed across multiple hardware devices and/or executed by two or more hardware devices (e.g., a server and a client hardware device). For example, the client hardware device may be implemented by an endpoint client hardware device (e.g., a hardware device associated with a human and/or machine user) or an intermediate client hardware device gateway (e.g., a radio access network (RAN)) that may facilitate communication between a server and an endpoint client hardware device. Similarly, the non-transitory computer readable storage medium may include one or more mediums. Further, although the example program is described with reference to the flowchart illustrated in FIG. 6, many other methods of implementing the example die shape control system 500 may alternatively be used. For example, the order of execution of the blocks of the flowchart may be changed, and/or some of the blocks described may be changed, eliminated, or combined. Additionally or alternatively, any or all of the blocks of the flow chart may be implemented by one or more hardware circuits (e.g., processor circuitry, discrete and/or integrated analog and/or digital circuitry, an FPGA, an ASIC, a comparator, an operational-amplifier (op-amp), a logic circuit, etc.) structured to perform the corresponding operation without executing software or firmware. The programmable circuitry may be distributed in different network locations and/or local to one or more hardware devices (e.g., a single-core processor (e.g., a single core CPU), a multi-core processor (e.g., a multi-core CPU, an XPU, etc.)). For example, the programmable circuitry may be a CPU and/or an FPGA located in the same package (e.g., the same integrated circuit (IC) package or in two or more separate housings), one or more processors in a single machine, multiple processors distributed across multiple servers of a server rack, multiple processors distributed across one or more server racks, etc., and/or any combination(s) thereof.

The machine readable instructions described herein may be stored in one or more of a compressed format, an encrypted format, a fragmented format, a compiled format, an executable format, a packaged format, etc. Machine readable instructions as described herein may be stored as data (e.g., computer-readable data, machine-readable data, one or more bits (e.g., one or more computer-readable bits, one or more machine-readable bits, etc.), a bitstream (e.g., a computer-readable bitstream, a machine-readable bitstream, etc.), etc.) or a data structure (e.g., as portion(s) of instructions, code, representations of code, etc.) that may be utilized to create, manufacture, and/or produce machine executable instructions. For example, the machine readable instructions may be fragmented and stored on one or more storage devices, disks and/or computing devices (e.g., servers) located at the same or different locations of a network or collection of networks (e.g., in the cloud, in edge devices, etc.). The machine readable instructions may require one or more of installation, modification, adaptation, updating, combining, supplementing, configuring, decryption, decompression, unpacking, distribution, reassignment, compilation, etc., in order to make them directly readable, interpretable, and/or executable by a computing device and/or other machine. For example, the machine readable instructions may be stored in multiple parts, which are individually compressed, encrypted, and/or stored on separate computing devices, wherein the parts when decrypted, decompressed, and/or combined form a set of computer-executable and/or machine executable instructions that implement one or more functions and/or operations that may together form a program such as that described herein.

In another example, the machine readable instructions may be stored in a state in which they may be read by programmable circuitry, but require addition of a library (e.g., a dynamic link library (DLL)), a software development kit (SDK), an application programming interface (API), etc., in order to execute the machine-readable instructions on a particular computing device or other device. In another example, the machine readable instructions may need to be configured (e.g., settings stored, data input, network addresses recorded, etc.) before the machine readable instructions and/or the corresponding program(s) can be executed in whole or in part. Thus, machine readable, computer readable and/or machine readable media, as used herein, may include instructions and/or program(s) regardless of the particular format or state of the machine readable instructions and/or program(s).

The machine readable instructions described herein can be represented by any past, present, or future instruction language, scripting language, programming language, etc. For example, the machine readable instructions may be represented using any of the following languages: C, C++, Java, C#, Perl, Python, JavaScript, HyperText Markup Language (HTML), Structured Query Language (SQL), Swift, etc.

As mentioned above, the example operations of FIG. 6 may be implemented using executable instructions (e.g., computer readable and/or machine readable instructions) stored on one or more non-transitory computer readable and/or machine readable media. As used herein, the terms non-transitory computer readable medium, non-transitory computer readable storage medium, non-transitory machine readable medium, and/or non-transitory machine readable storage medium are expressly defined to include any type of computer readable storage device and/or storage disk and to exclude propagating signals and to exclude transmission media. Examples of such non-transitory computer readable medium, non-transitory computer readable storage medium, non-transitory machine readable medium, and/or non-transitory machine readable storage medium include optical storage devices, magnetic storage devices, an HDD, a flash memory, a read-only memory (ROM), a CD, a DVD, a cache, a RAM of any type, a register, and/or any other storage device or storage disk in which information is stored for any duration (e.g., for extended time periods, permanently, for brief instances, for temporarily buffering, and/or for caching of the information). As used herein, the terms “non-transitory computer readable storage device” and “non-transitory machine readable storage device” are defined to include any physical (mechanical, magnetic and/or electrical) hardware to retain information for a time period, but to exclude propagating signals and to exclude transmission media. Examples of non-transitory computer readable storage devices and/or non-transitory machine readable storage devices include random access memory of any type, read only memory of any type, solid state memory, flash memory, optical discs, magnetic disks, disk drives, and/or redundant array of independent disks (RAID) systems. As used herein, the term “device” refers to physical structure such as mechanical and/or electrical equipment, hardware, and/or circuitry that may or may not be configured by computer readable instructions, machine readable instructions, etc., and/or manufactured to execute computer-readable instructions, machine-readable instructions, etc.

FIG. 6 is a flowchart representative of example machine readable instructions and/or example operations 600 that may be executed, instantiated, and/or performed by programmable circuitry to control a bonding of a die (e.g., the die 201) to a target (e.g., the wafer 104). The example machine-readable instructions and/or the example operations 600 of FIG. 6 begin at block 602, at which the die is identified. In some examples, multiple die are identified for placement onto the target.

At block 604, in some examples, the example shape analyzer 502 determines whether a shape model and/or shape information of the die exists and/or is accessible. If the shape model and/or the shape information is not available, control of the process proceeds to block 606. Otherwise, the process proceeds to block 608.

At block 606, additionally or alternatively, the example shape analyzer 502 causes and/or directs at least one sensor (e.g., the sensor 204) to measure the die (e.g., measure portions/areas of the die). In this example, the shape analyzer 502 causes and/or directs the sensor to measure multiple points of the die to generate and/or determine a surface/flexure/warpage profile of the die.

At block 608, the example shape model analyzer circuitry 508 obtains and/or accesses a shape model and/or a trained machine learning model from the data storage 510.

At block 610, according to examples disclosed herein, the shape analyzer 502 and/or the shape model analyzer circuitry 508 determines a shape, shape profile, warpage and/or flexure of the die. The shape analyzer 502 and/or the shape model analyzer circuitry 508 may make the determination based on sensor measurements and/or previously recorded data, for example. In some examples, the shape analyzer 502 and/or the shape model analyzer circuitry 508 utilize a shape profile of multiple points of at least one surface of the die.

At block 612, the example adjustment determiner circuitry 504 determines an adjustment of the shape and/or the flexure. In this example, the adjustment determiner circuitry 504 determines the adjustment to reduce an occurrence of voids between the die and the target. The adjustment can vary over time (e.g., a displacement that varies over time).

At block 614, the example displacement controller circuitry 506 causes the actuator and/or vacuum device/generator to adjust the shape/flexure profile of the die. According to example disclosed herein, a grid/array of actuators (e.g., a grid of pins) and/or vacuum apertures/openings are controlled by the displacement controller circuitry 506 to affect a shape and/or shape profile of the die across multiple directions/axes.

In some examples, at block 615, the shape analyzer 502 and/or the adjustment determiner circuitry 504 determines whether additional adjustments are to be performed. This determination may be based on real-time measurements of the shape/flexure profile of the die. If additional adjustments are to be performed, control of the process returns to block 612. Otherwise, the process proceeds to block 616.

At block 616, the example displacement controller circuitry 506 controls the placer to couple/bond the die to the target. In some examples, the displacement controller circuitry 506 controls the actuator and/or an array of vacuum apertures as well as movement of the placer.

At block 618, in some examples, it is determined by the shape analyzer 502 and/or the adjustment determiner circuitry 504 whether to repeat the process. If the process is to be repeated (block 618), control of the process returns to block 602. Otherwise, the process ends. The determination may be based on whether additional die are to be bonded/coupled to the target.

FIG. 7 is a block diagram of an example programmable circuitry platform 700 structured to execute and/or instantiate the example machine-readable instructions and/or the example operations of FIG. 6 to implement the die shape control system 500 of FIG. 5. The programmable circuitry platform 700 can be, for example, a server, a personal computer, a workstation, a self-learning machine (e.g., a neural network), a mobile device (e.g., a cell phone, a smart phone, a tablet such as an iPad™), a personal digital assistant (PDA), an Internet appliance, a DVD player, a CD player, a digital video recorder, a Blu-ray player, a gaming console, a personal video recorder, a set top box, a headset (e.g., an augmented reality (AR) headset, a virtual reality (VR) headset, etc.) or other wearable device, or any other type of computing and/or electronic device.

The programmable circuitry platform 700 of the illustrated example includes programmable circuitry 712. The programmable circuitry 712 of the illustrated example is hardware. For example, the programmable circuitry 712 can be implemented by one or more integrated circuits, logic circuits, FPGAs, microprocessors, CPUs, GPUs, DSPs, and/or microcontrollers from any desired family or manufacturer. The programmable circuitry 712 may be implemented by one or more semiconductor based (e.g., silicon based) devices. In this example, the programmable circuitry 712 implements the example shape analyzer 502, the example adjustment determiner circuitry 504, the example displacement controller circuitry 506, and the example shape model analyzer circuitry 508.

The programmable circuitry 712 of the illustrated example includes a local memory 713 (e.g., a cache, registers, etc.). The programmable circuitry 712 of the illustrated example is in communication with main memory 714, 716, which includes a volatile memory 714 and a non-volatile memory 716, by a bus 718. The volatile memory 714 may be implemented by Synchronous Dynamic Random Access Memory (SDRAM), Dynamic Random Access Memory (DRAM), RAMBUS® Dynamic Random Access Memory (RDRAM®), and/or any other type of RAM device. The non-volatile memory 716 may be implemented by flash memory and/or any other desired type of memory device. Access to the main memory 714, 716 of the illustrated example is controlled by a memory controller 717. In some examples, the memory controller 717 may be implemented by one or more integrated circuits, logic circuits, microcontrollers from any desired family or manufacturer, or any other type of circuitry to manage the flow of data going to and from the main memory 714, 716.

The programmable circuitry platform 700 of the illustrated example also includes interface circuitry 720. The interface circuitry 720 may be implemented by hardware in accordance with any type of interface standard, such as an Ethernet interface, a universal serial bus (USB) interface, a Bluetooth® interface, a near field communication (NFC) interface, a Peripheral Component Interconnect (PCI) interface, and/or a Peripheral Component Interconnect Express (PCIe) interface.

In the illustrated example, one or more input devices 722 are connected to the interface circuitry 720. The input device(s) 722 permit(s) a user (e.g., a human user, a machine user, etc.) to enter data and/or commands into the programmable circuitry 712. The input device(s) 722 can be implemented by, for example, an audio sensor, a microphone, a camera (still or video), a keyboard, a button, a mouse, a touchscreen, a trackpad, a trackball, an isopoint device, and/or a voice recognition system.

One or more output devices 724 are also connected to the interface circuitry 720 of the illustrated example. The output device(s) 724 can be implemented, for example, by display devices (e.g., a light emitting diode (LED), an organic light emitting diode (OLED), a liquid crystal display (LCD), a cathode ray tube (CRT) display, an in-place switching (IPS) display, a touchscreen, etc.), a tactile output device, a printer, and/or speaker. The interface circuitry 720 of the illustrated example, thus, typically includes a graphics driver card, a graphics driver chip, and/or graphics processor circuitry such as a GPU.

The interface circuitry 720 of the illustrated example also includes a communication device such as a transmitter, a receiver, a transceiver, a modem, a residential gateway, a wireless access point, and/or a network interface to facilitate exchange of data with external machines (e.g., computing devices of any kind) by a network 726. The communication can be by, for example, an Ethernet connection, a digital subscriber line (DSL) connection, a telephone line connection, a coaxial cable system, a satellite system, a beyond-line-of-sight wireless system, a line-of-sight wireless system, a cellular telephone system, an optical connection, etc.

The programmable circuitry platform 700 of the illustrated example also includes one or more mass storage discs or devices 728 to store firmware, software, and/or data. Examples of such mass storage discs or devices 728 include magnetic storage devices (e.g., floppy disk, drives, HDDs, etc.), optical storage devices (e.g., Blu-ray disks, CDs, DVDs, etc.), RAID systems, and/or solid-state storage discs or devices such as flash memory devices and/or SSDs.

The machine readable instructions 732, which may be implemented by the machine readable instructions of FIG. 6, may be stored in the mass storage device 728, in the volatile memory 714, in the non-volatile memory 716, and/or on at least one non-transitory computer readable storage medium such as a CD or DVD which may be removable.

FIG. 8 is a block diagram of an example implementation of the programmable circuitry 712 of FIG. 7. In this example, the programmable circuitry 712 of FIG. 7 is implemented by a microprocessor 800. For example, the microprocessor 800 may be a general-purpose microprocessor (e.g., general-purpose microprocessor circuitry). The microprocessor 800 executes some or all of the machine-readable instructions of the flowchart of FIG. 6 to effectively instantiate the circuitry of FIG. 5 as logic circuits to perform operations corresponding to those machine readable instructions. In some such examples, the circuitry of FIG. 5 is instantiated by the hardware circuits of the microprocessor 800 in combination with the machine-readable instructions. For example, the microprocessor 800 may be implemented by multi-core hardware circuitry such as a CPU, a DSP, a GPU, an XPU, etc. Although it may include any number of example cores 802 (e.g., 1 core), the microprocessor 800 of this example is a multi-core semiconductor device including N cores. The cores 802 of the microprocessor 800 may operate independently or may cooperate to execute machine readable instructions. For example, machine code corresponding to a firmware program, an embedded software program, or a software program may be executed by one of the cores 802 or may be executed by multiple ones of the cores 802 at the same or different times. In some examples, the machine code corresponding to the firmware program, the embedded software program, or the software program is split into threads and executed in parallel by two or more of the cores 802. The software program may correspond to a portion or all of the machine readable instructions and/or operations represented by the flowchart of FIG. 6.

The cores 802 may communicate by a first example bus 804. In some examples, the first bus 804 may be implemented by a communication bus to effectuate communication associated with one(s) of the cores 802. For example, the first bus 804 may be implemented by at least one of an Inter-Integrated Circuit (I2C) bus, a Serial Peripheral Interface (SPI) bus, a PCI bus, or a PCIe bus. Additionally or alternatively, the first bus 804 may be implemented by any other type of computing or electrical bus. The cores 802 may obtain data, instructions, and/or signals from one or more external devices by example interface circuitry 806. The cores 802 may output data, instructions, and/or signals to the one or more external devices by the interface circuitry 806. Although the cores 802 of this example include example local memory 820 (e.g., Level 1 (L1) cache that may be split into an L1 data cache and an L1 instruction cache), the microprocessor 800 also includes example shared memory 810 that may be shared by the cores (e.g., Level 2 (L2 cache)) for high-speed access to data and/or instructions. Data and/or instructions may be transferred (e.g., shared) by writing to and/or reading from the shared memory 810. The local memory 820 of each of the cores 802 and the shared memory 810 may be part of a hierarchy of storage devices including multiple levels of cache memory and the main memory (e.g., the main memory 714, 716 of FIG. 7). Typically, higher levels of memory in the hierarchy exhibit lower access time and have smaller storage capacity than lower levels of memory. Changes in the various levels of the cache hierarchy are managed (e.g., coordinated) by a cache coherency policy.

Each core 802 may be referred to as a CPU, DSP, GPU, etc., or any other type of hardware circuitry. Each core 802 includes control unit circuitry 814, arithmetic and logic (AL) circuitry (sometimes referred to as an ALU) 816, a plurality of registers 818, the local memory 820, and a second example bus 822. Other structures may be present. For example, each core 802 may include vector unit circuitry, single instruction multiple data (SIMD) unit circuitry, load/store unit (LSU) circuitry, branch/jump unit circuitry, floating-point unit (FPU) circuitry, etc. The control unit circuitry 814 includes semiconductor-based circuits structured to control (e.g., coordinate) data movement within the corresponding core 802. The AL circuitry 816 includes semiconductor-based circuits structured to perform one or more mathematic and/or logic operations on the data within the corresponding core 802. The AL circuitry 816 of some examples performs integer based operations. In other examples, the AL circuitry 816 also performs floating-point operations. In yet other examples, the AL circuitry 816 may include first AL circuitry that performs integer-based operations and second AL circuitry that performs floating-point operations. In some examples, the AL circuitry 816 may be referred to as an Arithmetic Logic Unit (ALU).

The registers 818 are semiconductor-based structures to store data and/or instructions such as results of one or more of the operations performed by the AL circuitry 816 of the corresponding core 802. For example, the registers 818 may include vector register(s), SIMD register(s), general-purpose register(s), flag register(s), segment register(s), machine-specific register(s), instruction pointer register(s), control register(s), debug register(s), memory management register(s), machine check register(s), etc. The registers 818 may be arranged in a bank as shown in FIG. 8. Alternatively, the registers 818 may be organized in any other arrangement, format, or structure, such as by being distributed throughout the core 802 to shorten access time. The second bus 822 may be implemented by at least one of an I2C bus, a SPI bus, a PCI bus, or a PCIe bus.

Each core 802 and/or, more generally, the microprocessor 800 may include additional and/or alternate structures to those shown and described above. For example, one or more clock circuits, one or more power supplies, one or more power gates, one or more cache home agents (CHAs), one or more converged/common mesh stops (CMSs), one or more shifters (e.g., barrel shifter(s)) and/or other circuitry may be present. The microprocessor 800 is a semiconductor device fabricated to include many transistors interconnected to implement the structures described above in one or more integrated circuits (ICs) contained in one or more packages.

The microprocessor 800 may include and/or cooperate with one or more accelerators (e.g., acceleration circuitry, hardware accelerators, etc.). In some examples, accelerators are implemented by logic circuitry to perform certain tasks more quickly and/or efficiently than can be done by a general-purpose processor. Examples of accelerators include ASICs and FPGAs such as those discussed herein. A GPU, DSP and/or other programmable device can also be an accelerator. Accelerators may be on-board the microprocessor 800, in the same chip package as the microprocessor 800 and/or in one or more separate packages from the microprocessor 800.

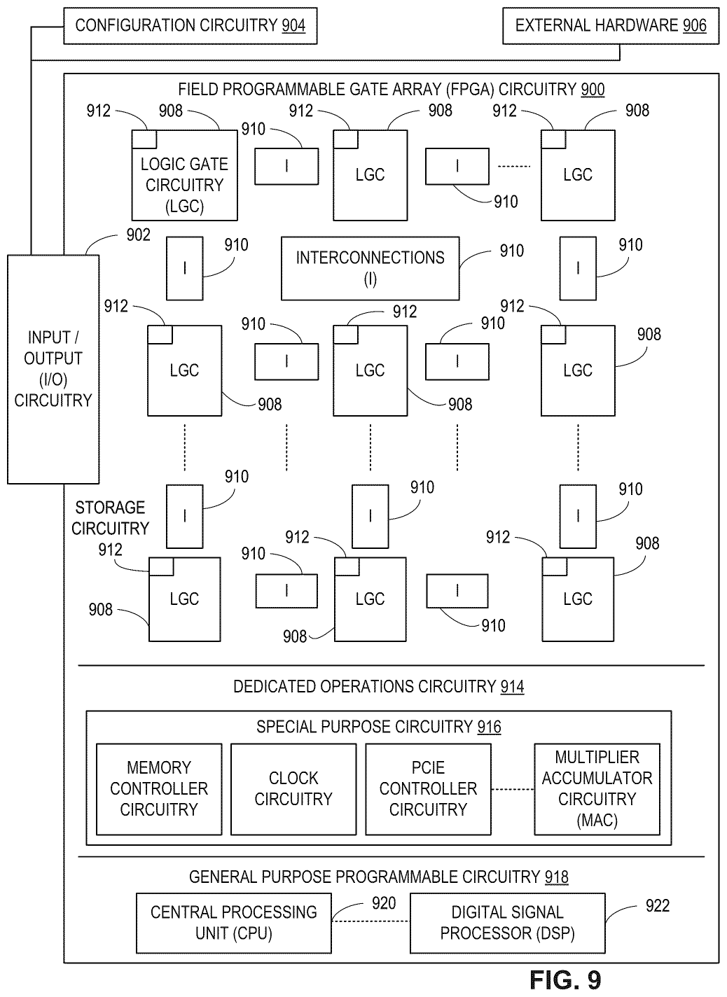

FIG. 9 is a block diagram of another example implementation of the programmable circuitry 712 of FIG. 7. In this example, the programmable circuitry 712 is implemented by FPGA circuitry 900. For example, the FPGA circuitry 900 may be implemented by an FPGA. The FPGA circuitry 900 can be used, for example, to perform operations that could otherwise be performed by the example microprocessor 800 of FIG. 8 executing corresponding machine readable instructions. However, once configured, the FPGA circuitry 900 instantiates the operations and/or functions corresponding to the machine readable instructions in hardware and, thus, can often execute the operations/functions faster than they could be performed by a general-purpose microprocessor executing the corresponding software.

More specifically, in contrast to the microprocessor 800 of FIG. 8 described above (which is a general purpose device that may be programmed to execute some or all of the machine readable instructions represented by the flowchart of FIG. 6 but whose interconnections and logic circuitry are fixed once fabricated), the FPGA circuitry 900 of the example of FIG. 9 includes interconnections and logic circuitry that may be configured, structured, programmed, and/or interconnected in different ways after fabrication to instantiate, for example, some or all of the operations/functions corresponding to the machine readable instructions represented by the flowchart of FIG. 6. In particular, the FPGA circuitry 900 may be thought of as an array of logic gates, interconnections, and switches. The switches can be programmed to change how the logic gates are interconnected by the interconnections, effectively forming one or more dedicated logic circuits (unless and until the FPGA circuitry 900 is reprogrammed). The configured logic circuits enable the logic gates to cooperate in different ways to perform different operations on data received by input circuitry. Those operations may correspond to some or all of the instructions (e.g., the software and/or firmware) represented by the flowchart of FIG. 6. As such, the FPGA circuitry 900 may be configured and/or structured to effectively instantiate some or all of the operations/functions corresponding to the machine readable instructions of the flowchart of FIG. 6 as dedicated logic circuits to perform the operations/functions corresponding to those software instructions in a dedicated manner analogous to an ASIC. Therefore, the FPGA circuitry 900 may perform the operations/functions corresponding to the some or all of the machine readable instructions of FIG. 6 faster than the general-purpose microprocessor can execute the same.

In the example of FIG. 9, the FPGA circuitry 900 is configured and/or structured in response to being programmed (and/or reprogrammed one or more times) based on a binary file. In some examples, the binary file may be compiled and/or generated based on instructions in a hardware description language (HDL) such as Lucid, Very High Speed Integrated Circuits (VHSIC) Hardware Description Language (VHDL), or Verilog. For example, a user (e.g., a human user, a machine user, etc.) may write code or a program corresponding to one or more operations/functions in an HDL; the code/program may be translated into a low-level language as needed; and the code/program (e.g., the code/program in the low-level language) may be converted (e.g., by a compiler, a software application, etc.) into the binary file. In some examples, the FPGA circuitry 900 of FIG. 9 may access and/or load the binary file to cause the FPGA circuitry 900 of FIG. 9 to be configured and/or structured to perform the one or more operations/functions. For example, the binary file may be implemented by a bit stream (e.g., one or more computer-readable bits, one or more machine-readable bits, etc.), data (e.g., computer-readable data, machine-readable data, etc.), and/or machine-readable instructions accessible to the FPGA circuitry 900 of FIG. 9 to cause configuration and/or structuring of the FPGA circuitry 900 of FIG. 9, or portion(s) thereof.

In some examples, the binary file is compiled, generated, transformed, and/or otherwise output from a uniform software platform utilized to program FPGAs. For example, the uniform software platform may translate first instructions (e.g., code or a program) that correspond to one or more operations/functions in a high-level language (e.g., C, C++, Python, etc.) into second instructions that correspond to the one or more operations/functions in an HDL. In some such examples, the binary file is compiled, generated, and/or otherwise output from the uniform software platform based on the second instructions. In some examples, the FPGA circuitry 900 of FIG. 9 may access and/or load the binary file to cause the FPGA circuitry 900 of FIG. 9 to be configured and/or structured to perform the one or more operations/functions. For example, the binary file may be implemented by a bit stream (e.g., one or more computer-readable bits, one or more machine-readable bits, etc.), data (e.g., computer-readable data, machine-readable data, etc.), and/or machine-readable instructions accessible to the FPGA circuitry 900 of FIG. 9 to cause configuration and/or structuring of the FPGA circuitry 900 of FIG. 9, or portion(s) thereof.

The FPGA circuitry 900 of FIG. 9, includes example input/output (I/O) circuitry 902 to obtain and/or output data to/from example configuration circuitry 904 and/or external hardware 906. For example, the configuration circuitry 904 may be implemented by interface circuitry that may obtain a binary file, which may be implemented by a bit stream, data, and/or machine-readable instructions, to configure the FPGA circuitry 900, or portion(s) thereof. In some such examples, the configuration circuitry 904 may obtain the binary file from a user, a machine (e.g., hardware circuitry (e.g., programmable or dedicated circuitry) that may implement an Artificial Intelligence/Machine Learning (AI/ML) model to generate the binary file), etc., and/or any combination(s) thereof). In some examples, the external hardware 906 may be implemented by external hardware circuitry. For example, the external hardware 906 may be implemented by the microprocessor 800 of FIG. 8.

The FPGA circuitry 900 also includes an array of example logic gate circuitry 908, a plurality of example configurable interconnections 910, and example storage circuitry 912. The logic gate circuitry 908 and the configurable interconnections 910 are configurable to instantiate one or more operations/functions that may correspond to at least some of the machine readable instructions of FIG. 6 and/or other desired operations. The logic gate circuitry 908 shown in FIG. 9 is fabricated in blocks or groups. Each block includes semiconductor-based electrical structures that may be configured into logic circuits. In some examples, the electrical structures include logic gates (e.g., And gates, Or gates, Nor gates, etc.) that provide basic building blocks for logic circuits. Electrically controllable switches (e.g., transistors) are present within each of the logic gate circuitry 908 to enable configuration of the electrical structures and/or the logic gates to form circuits to perform desired operations/functions. The logic gate circuitry 908 may include other electrical structures such as look-up tables (LUTs), registers (e.g., flip-flops or latches), multiplexers, etc.

The configurable interconnections 910 of the illustrated example are conductive pathways, traces, vias, or the like that may include electrically controllable switches (e.g., transistors) whose state can be changed by programming (e.g., using an HDL instruction language) to activate or deactivate one or more connections between one or more of the logic gate circuitry 908 to program desired logic circuits.

The storage circuitry 912 of the illustrated example is structured to store result(s) of the one or more of the operations performed by corresponding logic gates. The storage circuitry 912 may be implemented by registers or the like. In the illustrated example, the storage circuitry 912 is distributed amongst the logic gate circuitry 908 to facilitate access and increase execution speed.

The example FPGA circuitry 900 of FIG. 9 also includes example dedicated operations circuitry 914. In this example, the dedicated operations circuitry 914 includes special purpose circuitry 916 that may be invoked to implement commonly used functions to avoid the need to program those functions in the field. Examples of such special purpose circuitry 916 include memory (e.g., DRAM) controller circuitry, PCIe controller circuitry, clock circuitry, transceiver circuitry, memory, and multiplier-accumulator circuitry. Other types of special purpose circuitry may be present. In some examples, the FPGA circuitry 900 may also include example general purpose programmable circuitry 918 such as an example CPU 920 and/or an example DSP 922. Other general purpose programmable circuitry 918 may additionally or alternatively be present such as a GPU, an XPU, etc., that can be programmed to perform other operations.

Although FIGS. 8 and 9 illustrate two example implementations of the programmable circuitry 712 of FIG. 7, many other approaches are contemplated. For example, FPGA circuitry may include an on-board CPU, such as one or more of the example CPU 920 of FIG. 8. Therefore, the programmable circuitry 712 of FIG. 7 may additionally be implemented by combining at least the example microprocessor 800 of FIG. 8 and the example FPGA circuitry 900 of FIG. 9. In some such hybrid examples, one or more cores 802 of FIG. 8 may execute a first portion of the machine readable instructions represented by the flowchart of FIG. 6 to perform first operation(s)/function(s), the FPGA circuitry 900 of FIG. 9 may be configured and/or structured to perform second operation(s)/function(s) corresponding to a second portion of the machine readable instructions represented by the flowchart of FIG. 6, and/or an ASIC may be configured and/or structured to perform third operation(s)/function(s) corresponding to a third portion of the machine readable instructions represented by the flowchart of FIG. 6.

It should be understood that some or all of the circuitry of FIG. 5 may, thus, be instantiated at the same or different times. For example, same and/or different portion(s) of the microprocessor 800 of FIG. 8 may be programmed to execute portion(s) of machine-readable instructions at the same and/or different times. In some examples, same and/or different portion(s) of the FPGA circuitry 900 of FIG. 9 may be configured and/or structured to perform operations/functions corresponding to portion(s) of machine-readable instructions at the same and/or different times.

In some examples, some or all of the circuitry of FIG. 5 may be instantiated, for example, in one or more threads executing concurrently and/or in series. For example, the microprocessor 800 of FIG. 8 may execute machine readable instructions in one or more threads executing concurrently and/or in series. In some examples, the FPGA circuitry 900 of FIG. 9 may be configured and/or structured to carry out operations/functions concurrently and/or in series. Moreover, in some examples, some or all of the circuitry of FIG. 5 may be implemented within one or more virtual machines and/or containers executing on the microprocessor 800 of FIG. 8.

In some examples, the programmable circuitry 712 of FIG. 7 may be in one or more packages. For example, the microprocessor 800 of FIG. 8 and/or the FPGA circuitry 900 of FIG. 9 may be in one or more packages. In some examples, an XPU may be implemented by the programmable circuitry 712 of FIG. 7, which may be in one or more packages. For example, the XPU may include a CPU (e.g., the microprocessor 800 of FIG. 8, the CPU 920 of FIG. 9, etc.) in one package, a DSP (e.g., the DSP 922 of FIG. 9) in another package, a GPU in yet another package, and an FPGA (e.g., the FPGA circuitry 900 of FIG. 9) in still yet another package.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of referencing a semiconductor device (e.g., a transistor), a semiconductor die containing a semiconductor device, and/or an integrated circuit (IC) package containing a semiconductor die during fabrication or manufacturing, “above” is not with reference to Earth, but instead is with reference to an underlying substrate on which relevant components are fabricated, assembled, mounted, supported, or otherwise provided. Thus, as used herein and unless otherwise stated or implied from the context, a first component within a semiconductor die (e.g., a transistor or other semiconductor device) is “above” a second component within the semiconductor die when the first component is farther away from a substrate (e.g., a semiconductor wafer) during fabrication/manufacturing than the second component on which the two components are fabricated or otherwise provided. Similarly, unless otherwise stated or implied from the context, a first component within an IC package (e.g., a semiconductor die) is “above” a second component within the IC package during fabrication when the first component is farther away from a printed circuit board (PCB) to which the IC package is to be mounted or attached. It is to be understood that semiconductor devices are often used in orientation different than their orientation during fabrication. Thus, when referring to a semiconductor device (e.g., a transistor), a semiconductor die containing a semiconductor device, and/or an integrated circuit (IC) package containing a semiconductor die during use, the definition of “above” in the preceding paragraph (i.e., the term “above” describes the relationship of two parts relative to Earth) will likely govern based on the usage context.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified herein.

As used herein “substantially real time” refers to occurrence in a near instantaneous manner recognizing there may be real world delays for computing time, transmission, etc. Thus, unless otherwise specified, “substantially real time” refers to real time+1 second.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example, an integrated circuit may be implemented as one or more of an ASIC, an FPGA, a chip, a microchip, programmable circuitry, a semiconductor substrate coupling multiple circuit elements, a system on chip (SoC), etc.

Example methods, apparatus, systems, and articles of manufacture to enable die bonds with increased bonding and, thus, reliability are disclosed herein. Further examples and combinations thereof include the following:

Example 1 includes an apparatus to adjust a die for bonding to a target, the apparatus comprising interface circuitry, machine-readable instructions, and at least one processor circuit to be programmed by the machine-readable instructions to determine a shape profile of the die, determine an adjustment of the shape profile with respect to the bonding of the die to the target, and cause at least one of (i) an actuator or (ii) a vacuum device of a placer that carries the die to adjust the shape profile based on the determined adjustment.

Example 2 includes the apparatus as defined in example 1, further including a sensor to measure the shape profile of the die, the sensor to provide output therefrom to the interface circuitry.

Example 3 includes the apparatus as defined in example 2, wherein the sensor is to measure the shape profile of the die prior to the placer picking up the die.

Example 4 includes the apparatus as defined in any of examples 1 to 3, wherein the at least one of (i) the actuator or (ii) the vacuum device includes at least one pin to displace a portion of the die to adjust the shape profile.

Example 5 includes the apparatus as defined in example 4, wherein the at least one pin is one of a plurality of pins arranged in a grid to adjust the shape profile.

Example 6 includes the apparatus as defined in example 5, wherein the pins include apertures that define vacuum zones.

Example 7 includes the apparatus as defined in any of examples 1 to 5, wherein the placer includes the vacuum device having a grid of at least two independently controlled vacuum apertures.

Example 8 includes the apparatus as defined in any of examples 1 to 7, wherein one or more of the at least one processor circuit is to utilize a trained machine learning model to determine the adjustment.

Example 9 includes the apparatus as defined in example 8, wherein the machine learning model is trained based on die flexure with respect to bonding adhesion.

Example 10 includes a system for bonding a die to a target wafer, the system comprising a placer to place the die onto the target wafer, a sensor to measure a flexure of the die at least one of before or during bonding the die to the target wafer, and at least one of (i) an actuator or (ii) a vacuum generator to displace a first portion of the die relative to a second portion of the die based on the measured flexure.

Example 11 includes the system as defined in example 10, further including a controller to determine an adjustment of a shape of the die based on the flexure, and wherein the at least one of (i)) the actuator or (ii) the vacuum generator is to displace the first portion of the die relative to the second portion of the die based on the adjustment of the shape of the die.

Example 12 includes the system as defined in example 11, wherein the controller is to retrieve a shape model of the die from a database, and wherein the at least one of (i) the actuator or (ii) the vacuum generator is to displace the first portion of the die relative to the second portion of the die based on the shape model.

Example 13 includes the system as defined in any of examples 10 to 12, wherein the at least one of (i) the actuator or (ii) the vacuum generator includes an array of vacuum apertures corresponding to respective movable pins.

Example 14 includes the system as defined in any of examples 10 to 13, wherein the sensor is carried by the bond head.

Example 15 includes the system as defined in any of examples 10 to 14, wherein the at least one of (i) the actuator or (ii) the vacuum generator is to displace the first portion of the die while the die is placed onto the target wafer.

Example 16 includes the system as defined in any of examples 10 to 15, wherein the sensor is to measure the flexure of the die as the die is moved to the wafer via the bond head.

Example 17 includes a method of bonding a die to a target wafer, the method comprising determining a shape of the die, displacing at a first portion of the die relative to a second portion of the die based on the shape, and coupling the die to the target wafer with the at least the portion of the die displaced.

Example 18 includes the method of example 17, further including determining an adjustment of the die based on the shape, and wherein the displacing of the first portion of the die relative to the second portion of the die is based on the adjustment.

Example 19 includes the method of any of examples 17 or 18, wherein displacing the at least the portion of the die occurs while the die is being coupled to the target wafer.

Example 20 includes the method of any of examples 17 to 19, wherein determining the shape of the die is based on output from a sensor corresponding to an in-line die shape measurement.

From the foregoing, it will be appreciated that example systems, apparatus, articles of manufacture, and methods have been disclosed that enable improved die bonding, especially in die-to-wafer applications. Examples disclosed herein can improve yields of die-based wafers, for example. Examples disclosed herein can effectively adjust for and/or mitigate variability in shape, warpage and/or flexure of die, etc.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. An apparatus for adjusting a die for bonding to a target, the apparatus comprising:
interface circuitry;
machine-readable instructions; and
at least one processor circuit to be programmed by the machine-readable instructions to:
determine a shape profile of the die;
determine an adjustment of the shape profile with respect to the bonding of the die to the target; and
cause at least one of (i) an actuator or (ii) a vacuum device of a placer that carries the die to adjust the shape profile based on the determined adjustment.

2. The apparatus as defined in claim 1, further including a sensor to measure the shape profile of the die, the sensor to provide output therefrom to the interface circuitry.

3. The apparatus as defined in claim 2, wherein the sensor is to measure the shape profile of the die prior to the placer picking up the die.

4. The apparatus as defined in claim 1, wherein the at least one of (i) the actuator or (ii) the vacuum device includes at least one pin to displace a portion of the die to adjust the shape profile.

5. The apparatus as defined in claim 4, wherein the at least one pin is one of a plurality of pins arranged in a grid to adjust the shape profile.

6. The apparatus as defined in claim 5, wherein the pins include apertures that define vacuum zones.

7. The apparatus as defined in claim 1, wherein the placer includes the vacuum device having a grid of at least two independently controlled vacuum apertures.

8. The apparatus as defined in claim 1, wherein one or more of the at least one processor circuit is to utilize a trained machine learning model to determine the adjustment.

9. The apparatus as defined in claim 8, wherein the machine learning model is trained based on die flexure with respect to bonding adhesion.

10. A system for bonding a die to a target wafer, the system comprising:
a bond head to place the die onto the target wafer;
a sensor to measure a flexure of the die at least one of before or during bonding the die to the target wafer; and
at least one of (i) an actuator or (ii) a vacuum generator to displace a first portion of the die relative to a second portion of the die based on the measured flexure.

11. The system as defined in claim 10, further including a controller to determine an adjustment of a shape of the die based on the flexure, and wherein the at least one of (i) the actuator or (ii) the vacuum generator is to displace the first portion of the die relative to the second portion of the die based on the adjustment of the shape of the die.

12. The system as defined in claim 11, wherein the controller is to retrieve a shape model of the die from a database, and wherein the at least one of (i) the actuator or (ii) the vacuum generator is to displace the first portion of the die relative to the second portion of the die based on the shape model.

13. The system as defined in claim 10, wherein the at least one of (i) the actuator or (ii) the vacuum generator includes an array of vacuum apertures corresponding to respective movable pins.

14. The system as defined in claim 10, wherein the sensor is carried by the bond head.

15. The system as defined in claim 10, wherein the at least one of (i) the actuator or (ii) the vacuum generator is to displace the first portion of the die as the die contacts the target wafer.

16. The system as defined in claim 10, wherein the sensor is to measure the flexure of the die as the die is moved to the wafer via the bond head.

17. A method of bonding a die to a target wafer, the method comprising:
determining a shape of the die;
displacing a first portion of the die relative to second portion of the die based on the shape; and
coupling the die to the target wafer with the at least the portion of the die displaced.

18. The method of claim 17, further including determining an adjustment of the die based on the shape, and wherein the displacing of the first portion of the die relative to the second portion of the die is based on the adjustment.

19. The method of claim 17, wherein displacing the first portion of the die relative to the second portion of the die occurs while the die contacts the target wafer.

20. The method of claim 17, wherein determining the shape of the die is based on output from a sensor corresponding to an in-line die shape measurement.
